(19) United States
(12) Patent Application Publication
(10) Pub. No.: US 2022/0206100 A1
(43) Pub. Date: Jun. 30, 2022

(54) PSEUDO-RESISTANCE CALIBRATION CIRCUIT BASED ON SWITCHED CAPACITOR

(71) Applicants: Mingyi Chen, Shanghai (CN); Yuzhi Hao, Shanghai (CN); Yongfu Li, Shanghai (CN); Weifu Chen, Shanghai (CN)

(72) Inventors: Mingyi Chen, Shanghai (CN); Yuzhi Hao, Shanghai (CN); Yongfu Li, Shanghai (CN); Weifu Chen, Shanghai (CN)

(21) Appl. No.: 17/646,325

(22) Filed: Dec. 29, 2021

(30) Foreign Application Priority Data
Dec. 31, 2020 (CN) 202011630463.8

(51) Int. Cl. G01R 35/00; H03F 3/45

(52) U.S. Cl. CPC G01R 35/005; H03F 3/45475

(57) ABSTRACT

The present invention relates to an analog integrated circuit. Specifically, a pseudo resistor calibration circuit configured for precise adjustment of pseudo-resistor resistance on a circuit. A reference resistor is generated by the switched capacitor correction circuit, and its resistance value is only related to the capacitance value of the switched capacitor and the switching frequency. Using a parallel-to-series circuit design scheme and a voltage integrator to extract the control voltage to control the pseudo resistance, a pseudo resistance which is X*Y*Z times of the reference resistance can be obtained. The resistance of the pseudo-resistor is accurately adjustable so as to achieve good robustness to PVT fluctuations and improved linearity compared to traditional pseudo-resistors.

### CROSS REFERENCE TO RELATED APPLICATION

The Pursuant to 35 U.S.C. §119(a), this application claims the benefit of earlier filing date and right of priority to China Patent Application No. 202011630463.8, filed Dec. 31, 2020, the contents of which are all hereby incorporated by reference herein in its entirety.

### TECHNICAL FIELD

The invention relates to the technical field of analog integrated circuits, in particular to a pseudo-resistance calibration circuit based on switched capacitors.

### BACKGROUND

In recent years, the rapid development of analog integrated circuits and the continuous expansion of the biomedical market have made the integration of circuit design and biomedical treatment an irreversible trend. In various kinds of wearable physiological signal detection equipment, physiological signal acquisition amplifier with band-pass characteristics is needed to suppress the offset voltage of the electrode. To form a very low high-pass cut-off frequency (for example, ECG acquisition which needs to be less than 0.67 Hz), a very large capacitance or resistance is usually realized by using off-chip devices, which is not conducive to improving integration. Therefore, it is important for biomedical circuits to use on-chip devices to achieve extremely low high-pass cut-off frequencies.

Traditional methods to achieve extremely low on-chip high-pass cut-off frequency include using a large resistor to directly form the feedback network of the amplifier and a capacitor in parallel with the resistor to form a band-pass characteristic, and using a DSL (DC servo loop) to integrate the output signal and feed it back to the input. However, DSL still needs to form an extremely low frequency integrator, it is necessary to realize on-chip large resistance or large capacitance.

Due to the limited area on the chip, implementing large capacitors could waste a lot of chip area and increase the design cost. Therefore, it is a more reasonable choice to implement a G ohm (10⁹ Ω) resistor on the chip. In order to realize such resistance, traditional methods were implemented include utilizing switch capacitor (SC), duty cycle resistor (DCR), and pseudo resistor (PR). Using the SC and DCR method, the chip can achieve a resistance of several G ohms at most, but the resistance value is still small. To achieve the specified high-pass cutoff frequency, it is still necessary to implement a capacitor of the order of 100 pF on the chip, resulting in a waste of area. The use of PR can achieve a resistance of several T ohms, but the resistance is uncontrollable and will vary with the process, voltage, temperature (hereinafter “PVT”), and the voltage difference between the two ends of the device, thereby reducing the linearity of the amplifier.

Pseudo-resistance technology has been incorporated to the biomedical field, and a variety of pseudo-resistance correction technologies have been developed to achieve controllable resistance and improve the robustness to PVT. Using a digital-to-analog converter to provide a bias voltage for the pseudo resistor can achieve controllable resistance and good linearity, but its resistance is less robust to PVT. On the other hand, using a current source proportional to the absolute temperature to bias the pseudo-resistance can achieve precise controllable resistance and good PVT robustness, however it can only work near the set operating point, and its linear region of the output signal is small.

### SUMMARY

Various embodiments of the present disclosure relate to a method and an apparatus for a pseudo-resistance calibration circuit based on switched capacitor. Specifically, the present invention proposes a low-power, small-area pseudo-resistor multiplexing calibration circuit to simultaneously solve the problems of poor PVT robustness, small output signal linear region, and inaccurate control of the resistance of the existing pseudo-resistance calibration circuit described above.

In some implementations, a low-power, small-area pseudo-resistance calibration circuit capable of multiplexing multiple pseudo-resistors is presented. The pseudo-resistance calibration circuit includes a switched capacitor calibration loop (1), a voltage integrator (2), and a level conversion module (3).

In some implementations, the switched capacitor calibration loop (1) consists of a switched capacitor (11), a feedback loop (12) (consisting of an operational amplifier and Y parallel P-type metal oxide semiconductor field effect transistors) and a current mirror with X:1 (13) current ratio.

In some implementations, the switched capacitor (11) is composed of two CMOS switches (12) and a capacitor (C), the two switches (12) are connected end to end and the intermediate node is connected to one end of the capacitor (C), and the other end of the capacitor (C) is grounded. The other ports of the two switches (12) are respectively connected to the port of the current mirror (13) through which X times of the current flows and a constant potential (V_{cm}). The signal that controls the on and off of the CMOS switch is generated by an additional control circuit.

In some implementations, the current mirror (13) is composed of two P-type transistors (M1, M2) with the same channel length and width ratio of X:1, wherein the gate of the P-type transistor (M1) with X times width is connected to the drain to form a diode connection. In addition, the generated voltage is used to control the gate voltage of the two P-type transistors (M1, M2) in the current mirror (13). The drain of the p-type transistor (M1) through which X times of the current in the current mirror (13) is connected to one end of the switched capacitor (11). The drain of p-type transistor (M2) through which 1 time of the current in the current mirror (13) is connected to the source of the Y parallel P-type transistors in the feedback loop (12), the body terminal of the Y parallel P-type transistors is connected to the source, and the drain stage is connected to a constant potential (V_{cm}) at the same time, the other end of the switched capacitor (11) is also connected to the constant potential (V_{cm}). The gate voltage of the Y P-type transistors connected in parallel is controlled by the output voltage of the operational amplifier. The positive input port of the operational amplifier is connected to the drain of M1 in the current mirror. The negative input port of the operational amplifier is connected to the drain of M2 in the current mirror. The voltage integrator (2) is composed of a switched capacitor integrator, which integrates the gate-source voltages (V_{gs}) of Y P-type transistors connected in parallel in a working cycle of the switched capacitor calibration loop, and outputs the average value of V_{gs} in a working cycle. The switched capacitor integrator has three working states, which are reset, sampling, and integrating. The state switching signal between different states is generated by an additional control circuit.

In some implementations, the level shifter (3) is composed of four switches and a capacitor, with two states of sampling and calibration. In the sampling state, when the output of the voltage integrator (2) is stable, the output of the voltage integrator (2) relative to the constant potential (V_{cm}) is sampled, and the voltage is stored on the capacitor. In the calibration state, the voltage on the sampling capacitor is applied to the gate-source capacitance of the pseudo resistor (4), and the voltage is used to calibrate the V_{gs} of the pseudo resistor (4) to achieve the purpose of correcting the resistance of the pseudo resistor. There is a capacitor between the gate and the source of the pseudo resistor (4) to store the voltage. This voltage can be used to control the resistance of the pseudo resistor in real time. The pseudo resistor (4) is composed of Z P-type transistors in series with a switch capacitor. The Y P-type transistors connected in parallel in the correction circuit 1 have the same size.

In some implementations, a design method maybe applied based on the above-mentioned pseudo-resistance calibration circuit including switched capacitors, which takes the resistance of the switched capacitor (11) in the calibration loop as the reference resistance, the value of the reference resistance being determined by the frequency of the switch in the switched capacitor (11). This signal is generated by an additional circuit control unit. Through the joint action of the current mirror (13) and the feedback loop (12), the resistance of each of the Y parallel P-type transistors in the feedback loop is calibrated to X*Y times of the resistance of the switched capacitor. Since the gate-source voltage (V_{gs}) of the transistor is not fixed during the operation of the switched-capacitor calibration circuit (1), a voltage integrator (2) is introduced to integrate the gate-source voltage (V_{gs}) in a working period and output the average value in a period. The level shifter (3) is used to sample the output voltage of the integrator to correct the gate-source voltage (V_{gs}) of the pseudo resistor (4), and to achieve the purpose of controlling the resistance of the pseudo resistor. The pseudo-resistor (4) is composed of Z P-type transistors in series, and finally the resistance of the pseudo resistor is calibrated to X*Y*Z times the resistance of the switched capacitor. At the same time, since the reference resistor is composed of a switched capacitor (11), its resistance is easy to adjust and will not be affected by PVT fluctuations.

The advantage of the present invention is that the resistance value of the pseudo resistor is amplified to X*Y*Z times of the resistance value of the switched capacitor through the circuit design scheme of a switched capacitor calibration loop and a parallel to series connection. In addition, the resistance of the pseudo resistor is adjustable, and the robustness of the pseudo resistor to PVT is improved. The gate-source voltage of the pseudo resistor will not change with the voltage across the pseudo resistor, which improves the linearity of the resistor.

### BRIEF DESCRIPTION OF THE DRAWINGS

FIG. 1 shows a schematic diagram of the overall structure of the present invention;

FIG. 2 shows a schematic diagram of the pseudo-resistance calibration circuit 200 of the present invention;

FIG. 3 shows a schematic diagram of the pseudo resistor structure 300 of the present invention;

FIG. 4 shows a schematic diagram of the working sequence 400 of the present invention;

FIG. 5 shows a schematic diagram of the operational amplifier 500 used in the present invention;

FIG. 6 shows the relationship 600 between the pseudo-resistance value and the frequency of the switched capacitor;

FIG. 7 shows the comparison of the resistance value changes of the calibrated pseudo resistance and the conventional pseudo resistance under different temperatures and three process corners (tt, ff, ss);

FIG. 8 shows a comparison of the resistance value changes of the calibrated pseudo resistance and the conventional pseudo resistance under different power supply voltages and three process corners (tt, ff, ss); and

FIG. 9 shows a comparison of the linearity of the calibrated pseudo resistor and the conventional pseudo resistor.

With regard to the description of the drawings, the same or similar reference numerals may be used for the same or similar components.

### DETAILED DESCRIPTION OF THE DISCLOSURE

The specific implementation of the present invention will be described in detail below with reference to the drawings and preferred embodiments.

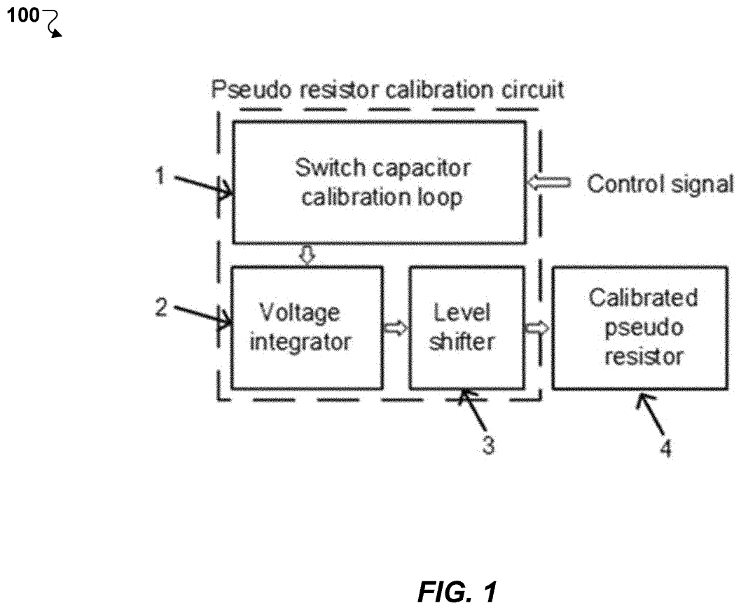

As shown in FIG. 1, the present invention provides an example pseudo resistor calibration circuit 100 based on switched capacitors. Through a switched capacitor calibration loop and a parallel-to-series circuit design scheme, the resistance of the pseudo resistance is amplified to X*Y*Z times of the resistance of the switched capacitor. In this example, the resistance value of the pseudo resistor is adjustable, and the robustness of the pseudo resistor under different PVTs is improved. The gate source voltage (V_{gs}) of the pseudo resistor does not change with the voltage across the pseudo resistor, which improves the linearity of the resistor.

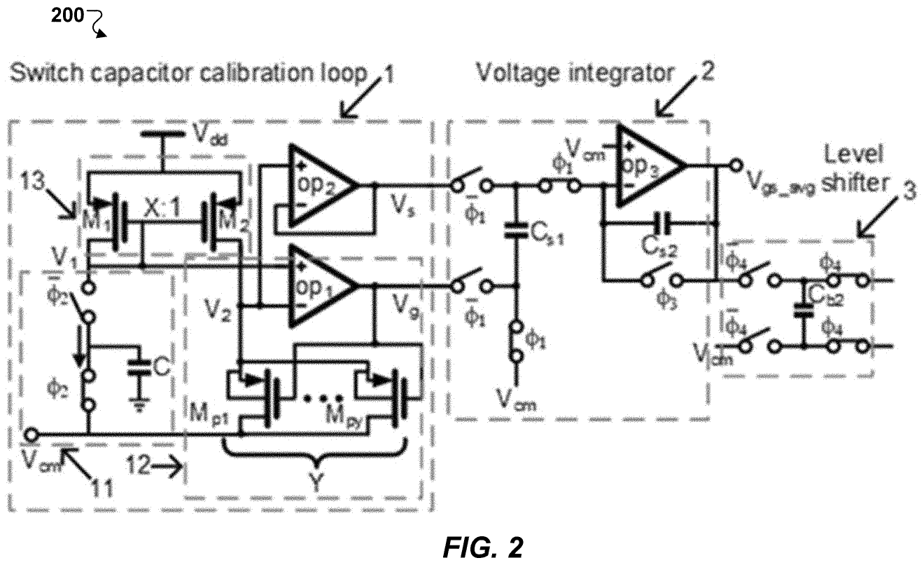

As shown in FIG. 2, an example structure of the pseudo resistor calibration circuit is formed based on switched capacitors includes switched capacitor calibration loop 1, voltage integrator 2, and level shifter 3.

In this example, the switched capacitor calibration loop 1 consists of a switched capacitor 11, a feedback loop 12 (consisting of an operational amplifier and Y parallel P-type metal oxide semiconductor field effect transistors), and a current mirror with X:1 (13) current ratio. The switched capacitor 11 is composed of two CMOS switches and a capacitor, the two CMOS switches being connected end to end and the intermediate node being connected to one end of the capacitor, and the other end of the capacitor being grounded. The other ports of the two switches are respectively connected to the port of the current mirror 13 through which X times of the current flows and a constant potential (V_{cm}). The signal (ϕ₂ and ϕ̅₂̅) that controls the on and off of the CMOS switches is generated by an additional control circuit.

In this example, the current mirror 13 is composed of two P-type transistors (M₁, M₂) with the same channel length and width ratio of X:1, wherein the gate of the P-type transistor (M₁) with X times width is connected to the drain to form a diode connection. In addition, the generated voltage is used to control the gate voltage of the two P-type transistors (M₁, M₂) in the current mirror 13. The drain of the p-type transistor (M₁) through which X times of the current in the current mirror 13 is connected to one end of the switched capacitor 11. Further the drain of p-type transistor (M₂) through which 1 time of the current in the current mirror 13 is connected to the source of the Y parallel P-type transistors in the feedback loop 12, the body terminal of the Y parallel P-type transistors being connected to the source, and the drain being connected to a constant potential (V_{cm}) at the same time, the other end of the switched capacitor 11 being also connected to the constant potential (V_{cm}). The gate voltage of the Y P-type transistors (Mₚ₁˜M_{py}) connected in parallel is controlled by the output voltage of the operational amplifier. The positive input port of the operational amplifier is connected to the drain of M1 in the current mirror. The negative input port of the operational amplifier is connected to the drain of M2 in the current mirror. Under the combined action of the current mirror 13 and the feedback loop 12, the current flowing through each of the Y parallel p-type transistors is one in X*Y times of the switching capacitor 11, and V₁ is equal to V₂. The resistance of each transistor in the parallel P-type transistor is X*Y times of the switching capacitor. The transistor operates in the sub threshold region, and its resistance value is only controlled by V_{gs} voltage. The gate voltage of the transistor is determined by the output of the operational amplifier in the feedback loop 12.

In this example, the voltage integrator 2 is composed of a switched capacitor integrator, which integrates the gate-source voltages (V_{gs}) of Y P-type transistors connected in parallel in a working cycle of the switched capacitor calibration loop, and outputs the average value of V_{gs} in a working cycle. The switched capacitor integrator has three working states, which are reset, sampling, and integrating, these working states being controlled by ϕ₃, ϕ̅₂̅ and ϕ₁ signals respectively. The state switching signal between different states is generated by an additional control circuit. In the voltage integrator 2 module, C_{S1} is the sampling capacitance and C_{S2} is the integrating capacitance. In the sampling phase, the sampling capacitor C_{S1} samples V_{gs} of Y transistors in parallel. In the integration phase, the charge on the sampling capacitor C_{S1} is transferred to the integration capacitor C_{S2} . The sampling capacitance C_{S1} is proportional to the capacitance of the integrating capacitance C_{S2} so that the voltage output by the integrator in each cycle is the average value of Y transistors V_{gs} in one cycle.

In this example, the level shifter 3 is composed of four switches (ϕ₄ and ϕ̅₄̅) and a capacitor (Cb₂), and has two states of sampling and calibration. In the sampling phase, when the output of the voltage integrator 2 is stable, the output voltage of the integrator 2 relative to the constant potential (V_{cm}) is sampled, and the voltage is stored on the capacitor (C_{b2}). In the calibration phase, the voltage on the sampling capacitor (Cb₂) is applied to the gate-source capacitance (C_{b1}) of the pseudo resistor (4), and the voltage is used to calibrate the V_{gs} of the pseudo resistor (4) to achieve the purpose of calibrating the resistance of the pseudo resistor.

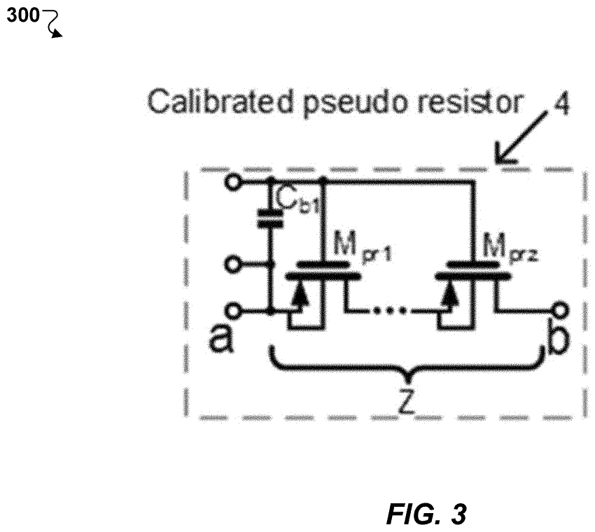

FIG. 3 is an example structural diagram 300 of calibrated pseudo resistor 4. In this example, there is a capacitor (C_{b1}) between the gate and the source of the pseudo resistor 4 to store the voltage. This voltage can be used to control the resistance of the pseudo resistor in real time. When the calibration circuit reaches a stable working state, the voltage on the capacitor C_{b1} reaches a stable state. The charge on the level shifter module 3 is only used to compensate the error caused by leakage current on C_{b}. The pseudo resistor 4 is composed of Z p-type transistors in series. It has the same size as the Y p-type transistors in parallel in the switched capacitor calibration loop circuit 1. The effect of calibrating the resistance of the pseudo resistance 4 to X*Y*Z times of the resistance of the switching capacitor is achieved. At the same time, since the reference resistance is composed of switching capacitor 11, its resistance value is easy to adjust and will not be affected by PVT fluctuation.

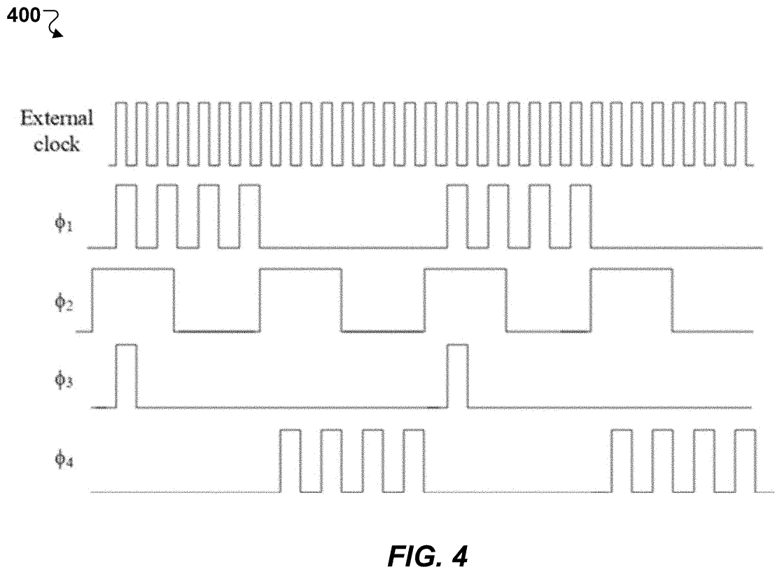

FIG. 4 shows an example timing 400 of each switch in the pseudo resistance calibration circuit based on switched capacitor is shown. In circuit ϕ₁, ϕ₂, ϕ₃, and ϕ₄ are generated by the clock signal. The following is an example, in one cycle of ϕ₂ signal, the switched capacitor 11 completes a charge and discharge. The switched capacitor integrator controlled by ϕ₁ signal performs four sampling integrals in one cycle of ϕ₂ signal. The integrator is reset by ϕ₃ signal before the integrator works. In the next cycle of ϕ₂ signal, the integrator no longer works, but keeps the output voltage. The output voltage is sampled by the level shifter controlled by ϕ₄ signal. The sampled voltage is used to calibrate the voltage on the capacitance between gate and source in pseudo resistance 4, so as to control the resistance value of pseudo resistance.

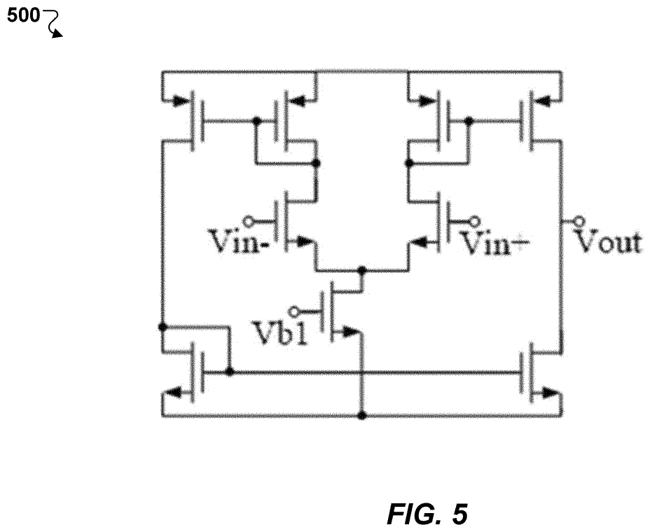

As shown in FIG. 5, an example operational amplifier 500 is used in the pseudo resistance calibration loop circuit based on switched capacitor.

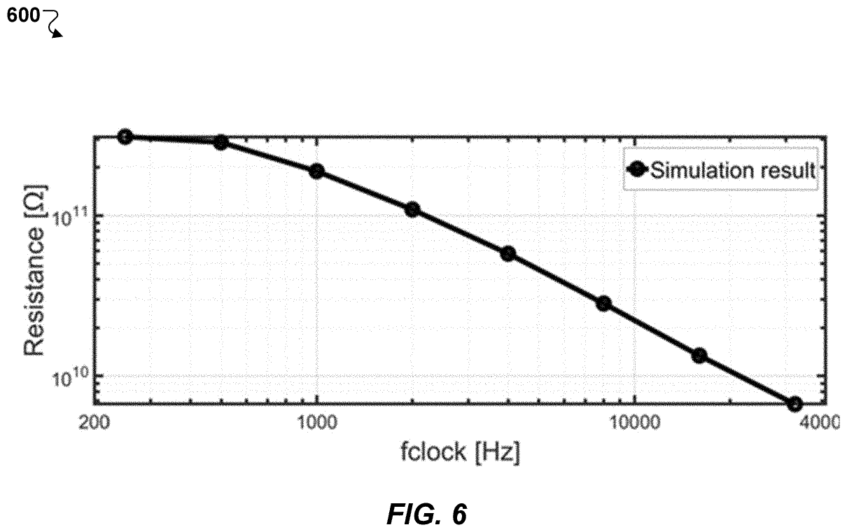

FIG. 6 shows an example resistance-clock relationship 600 between the pseudo resistance value and the clock frequency. In the above example, the clock frequency is 8 times of the ϕ₂ signal frequency. Therefore, it also shows the relationship between the pseudo resistance value and the ϕ₂ signal frequency.

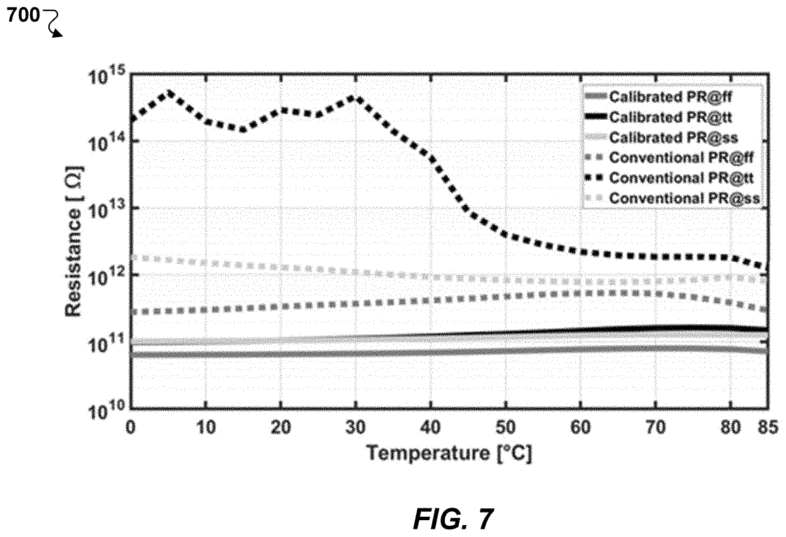

As shown in FIG. 7, in order to compare the calibrated pseudo resistance with the conventional pseudo resistance at different process corners of 0-85° C., the example results show that the maximum fluctuation of resistance value is reduced from 1800 times to 2 times.

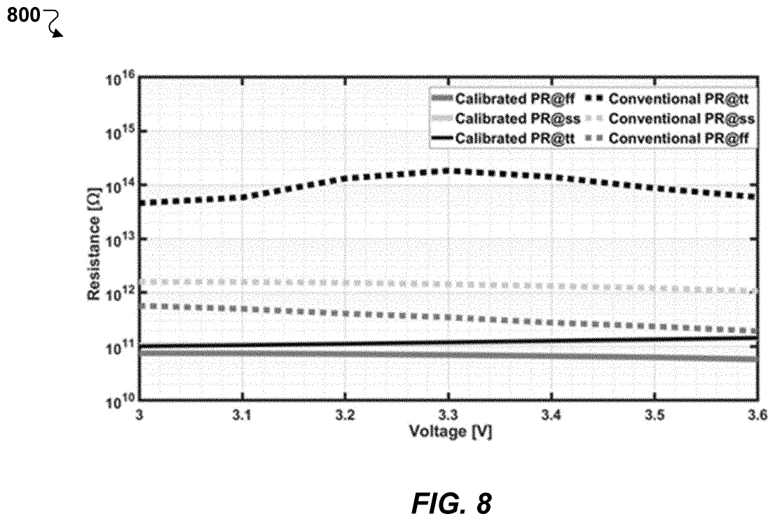

As shown in FIG. 8, taking the 3.3V power supply voltage as an example, under different process corners, an example power supply voltage fluctuates from 3V to 3.6V, and the corresponding example resistance fluctuation of the calibrated pseudo resistance is reduced from 530 times to 2.5 times compared with the conventional pseudo resistance.

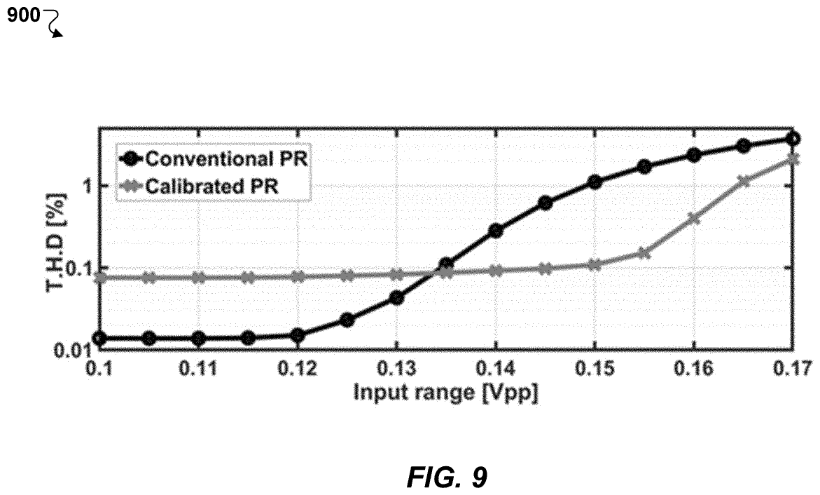

FIG. 9 shows an example comparison of the linearity of the calibrated pseudo resistor with that of the conventional pseudo resistor, and the range of resistor linearity is increased by 10%.

The invention generates a reference resistance through the switched capacitor calibration loop circuit 1. The reference resistance is composed of switching capacitor, and its resistance value is only related to the capacitance value of switching capacitor and switching frequency, but has nothing to do with the fluctuation of PVT. Using the circuit design scheme of parallel to series and the voltage integrator 2 to extract the control voltage to control the pseudo resistor 4, the pseudo resistor 4 with the resistance value of XYZ times the reference resistance can be obtained. The resistance value of the calibrated pseudo resistance 4 is tunable, the robustness to PVT fluctuation is stable, and the linearity is higher than that of the conventional pseudo resistance.

Although the specific embodiments of the invention have been described above, those skilled in the art should understand that these are only examples. A variety of changes or modifications can be made to these embodiments without departing from the and essence of the invention. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

What is claimed is:

1. A pseudo resistor calibration circuit, comprising:
a switched capacitor calibration loop that is configured to generate a reference resistor with a reference resistance relevant to a clock frequency, amplify the reference resistance by X*Y times, and output a relative voltage of metal-oxide-semiconductor (MOS) transistors, the switched capacitor calibration loop comprising:
a pair of current mirrors with a current ratio of 1:X and is configured to reduce a current by X times;
a switched capacitor consisting of two switches and a capacitor, the switched capacitor being configured to generate a reference resistor which is determined by the clock frequency and capacitance of the capacitor; and
a feedback loop consisting of a first operational amplifier and Y MOS transistors that are connected in parallel, wherein the first operational amplifier is configured to ensure a same voltage at its positive and negative inputs by adjusting a gate voltage of the Y MOS transistors, wherein an equivalent resistance of the Y MOS transistors is X times of the reference resistance, and wherein the equivalent resistance of one of the Y MOS transistors is amplified by X*Y times;
a voltage integrator configured to sample an output voltage of the first operational amplifier and a second operational amplifier, wherein an averaged output voltage is equivalent to the equivalent gate-source voltage of the Y MOS transistors in one working cycle; and
a level shifter configured to sample the output voltage of the voltage integrator and transfer the sampled output voltage to a bootstrap capacitor of a calibrated pseudo resistor, wherein the bootstrap capacitor is configured to store a voltage to control a resistance value of the calibrated pseudo resistor, wherein the calibrated pseudo resistor is consisted of Z MOS transistors in series, a gate-source voltage of the Z MOS transistors being decided by the voltage stored on the bootstrap capacitor and equal to the equivalent gate-source voltage of Y MOS transistor in the calibration loop, and wherein a resistance value of the calibrated pseudo resistor is calibrated to X*Y*Z times of the reference resistor.

2. The pseudo resistor calibration circuit of claim 1, wherein the Y MOS transistors and Z MOS transistors have a same aspect ratio, the body of the Y MOS transistors and Z MOS transistors being connected to a source to reduce body effect.

3. The pseudo resistor calibration circuit of claim 1, wherein the two switches of the reference resistor are connected in series at a connection node, wherein one end of the capacitor of the reference resistor is connected to the connection node and the other end of the capacitor is connected to the ground, wherein one end of the two switches is connected to a port with X times current of the current mirror and the other end of the two switches is connected to a reference voltage.

4. The pseudo resistor calibration circuit of claim 1, wherein the two switches comprise CMOS switches consist of a NMOS transistor and a PMOS transistor.

5. The pseudo resistor calibration circuit of claim 1, wherein the CMOS switch comprises a non-overlapping clock generation circuit that is configured to generate two non-overlapping clock signals to control the NMOS transistor and the PMOS transistor respectively.

6. The pseudo resistor calibration circuit of claim 1, wherein the voltage integrator is composed of switched capacitor integrator.

7. The pseudo resistor calibration circuit of claim 6, wherein the switched capacitor integrator is composed of a sample capacitor and an integral capacitor, the sample capacitor being configured to sample the gate-source voltage for multiple times in one cycle and the averaged voltage of the integral capacitor.

8. The pseudo resistor calibration circuit of claim 7, wherein a relative value of the output voltage and the reference voltage is sampled by the sample capacitor of the level shifter.

9. The pseudo resistor calibration circuit of claim 6, wherein the switched capacitor integrator is configured to reset at an end of each working cycle and set the voltage on the integrating capacitor to zero.

10. The pseudo resistor calibration circuit of claim 1, further comprises a reference generation circuit that is configured to generate a reference voltage for the pseudo resistor calibration circuit.

11. The pseudo resistor calibration circuit of claim 1, further comprises a reference generation circuit that is configured to generate a reference current for the first operational amplifier.

12. The pseudo resistor calibration circuit of claim 1, wherein the first operational amplifier is configured as low mismatch to reduce offset.

13. The pseudo resistor calibration circuit of claim 1, further comprises a clock generation circuit that is configured to generate a clock for controlling the reference resistance.

14. The pseudo resistor calibration circuit of claim 1, further comprises a control logic circuit that is configured to generate signal to control the switches in the pseudo resistor calibration circuit according to the clock frequency.

15. The pseudo resistor calibration circuit of claim 14, wherein the generated control signals are non-overlapping.

16. The pseudo resistor calibration circuit of claim 1, wherein the bootstrap capacitor is shared by the Y MOS transistors connected in series.

17. The pseudo resistor calibration circuit of claim 1, wherein the MOS transistors have a same channel length and width, and wherein the current ratio depends on the number of MOS transistors connected in parallel.

18. The pseudo resistor calibration circuit of claim 1, wherein the pseudo resistor calibration circuit is configured to operate at four working states comprising:
a first state to reset the voltage stored on the integrating capacitor to zero;
a second state in which the sample capacitor is configured to sample the source-gate voltage of the Y MOS transistors in parallel in one working cycle;
a third state in which the voltage integrator is configured to output the average voltage of source-gate voltage in one working cycle; and
a fourth state in which the sample capacitor of the level shifter is configured to sample the relative value of output voltage and reference voltage and transfer the sample voltage to the bootstrap capacitor.

19. The pseudo resistor calibration circuit of claim 18, wherein the one working cycle refers to a period in which the capacitor of the switching capacitor is fully charged and discharged at one time.

20. The pseudo resistor calibration circuit according to claim 1, wherein the pseudo resistor calibration circuit is configured to works periodically to supplement the charge leakage on the bootstrap capacitor and compensate for the change of working temperature and the fluctuation of power supply voltage.
